(19) United States
(12) Patent Application Publication
(10) Pub. No.: US 2015/0115071 A1
(43) Pub. Date: Apr. 30, 2015

(54) OIL SUPPLY NOZZLE AND MANUFACTURING METHOD THEREOF

(71) Applicant: SAMSUNG ELECTRO-MECHANICS CO., LTD., Suwon-si (KR)

(72) Inventors: Min Chul Go, Suwon-si (KR); Chun Mo Sung, Suwon-si (KR)

(73) Assignee: SAMSUNG ELECTRO-MECHANICS CO., LTD., Suwon-si (KR)

(21) Appl. No.: 14/174,820

(22) Filed: Feb. 6, 2014

(30) Foreign Application Priority Data
Oct. 31, 2013 (KR) 10-2013-0131093

(51) Int. Cl. F16N 21/04; F16C 33/00; C23C 14/34; B23P 15/00

(52) U.S. Cl. CPC F16N 21/04; B23P 15/00; F16C 33/00; C23C 14/34
USPC 239/600; 29/898.1; 29/464; 204/192.1

(57) ABSTRACT

There is provided an oil supply nozzle including a micro-needle, and a needle holder to which the micro-needle is inserted and fixed with an adhesive, wherein the needle holder includes a coupling hole formed to allow the needle holder to be inserted into an oil injection apparatus, and an injection hole connected to the coupling hole and having the micro-needle inserted thereinto, and the insertion hole and the coupling hole have a guide hole at a point of connection therebetween.

### CROSS-REFERENCE TO RELATED APPLICATION

This application claims the benefit of Korean Patent Application No. 10-2013-0131093, filed on Oct. 31, 2013, with the Korean Intellectual Property Office, the disclosure of which is incorporated herein by reference.

### BACKGROUND

The present disclosure relates to an oil supply nozzle and a manufacturing method thereof.

A small-sized spindle motor used for a hard disk drive (HDD) generally performs a function of rotating a disk to enable a magnetic head to write data to or read data from the disk.

The small-sized spindle motor is used in such an HDD.

A hydrodynamic bearing assembly has been used in such a small-sized spindle motor. Oil is interposed between a shaft and a sleeve of the hydrodynamic bearing assembly, such that the shaft is supported by fluid pressure generated in the oil.

In this case, in order to inject the oil into the hydrodynamic bearing assembly used for the spindle motor, a separate oil injection apparatus is required. The oil discharged from a tip of the oil injection apparatus is injected into a gap of the hydrodynamic bearing assembly to fill the inside of the hydrodynamic bearing assembly.

However, in accordance with the recent trend for the miniaturization of spindle motors, a size of the gap formed in the hydrodynamic bearing assemblies thereof has also been reduced and an oil injection apparatus according to the related art is not suitable for injecting oil into a micro-sized gap formed therein, such that the injection of oil thereinto may be problematic.

### SUMMARY

An aspect of the present disclosure may provide an oil supply nozzle employing a micro-needle so that oil may be easily injected into a micro-gap, and a manufacturing method thereof.

An aspect of the present disclosure may also provide an oil supply nozzle capable of securing reliability by improving pulling-out force of the micro-needle, and a manufacturing method thereof.

According to an aspect of the present disclosure, an oil supply nozzle may include: a micro-needle; and a needle holder into which the micro-needle is inserted and fixed with an adhesive, wherein the needle holder includes a coupling hole formed to allow the needle holder to be inserted into an oil injection apparatus, and an injection hole connected to the coupling hole and having the micro-needle inserted thereinto, and the insertion hole and the coupling hole have a guide hole at a point of connection therebetween.

The guide hole may be formed to have a diameter smaller than that of the coupling hole and larger than that of the insertion hole.

The insertion hole may have at least one reservoir groove formed in an inner wall thereof in order to increase a contact area with the adhesive.

The insertion hole may have an inner wall formed to have a degree of surface roughness greater than that of other portions of the needle holder.

According to another aspect of the present disclosure, a manufacturing method of an oil supply nozzle may include: providing a micro-needle; providing a needle holder including a coupling hole to allow for insertion into an oil injection apparatus, including an insertion hole into which the micro-needle is inserted, and including a guide hole at a point at which the insertion hole and the coupling hole are connected to each other; inserting the micro-needle into the insertion hole; inserting a stopper into the coupling hole so that an end of the stopper is disposed in the guide hole; and injecting an adhesive into a gap between an inner wall of the insertion hole and the micro-needle.

The method may further include forming the inner wall of the insertion hole to have a degree of surface roughness greater than that of other portions of the needle holder.

The method may further include forming at least one reservoir groove in the inner wall of the insertion hole.

In the inserting of the micro-needle into the insertion hole, an end of the micro-needle may be disposed in the guide hole so that the end of the micro-needle is in contact with an end of the leakage preventing jig.

In the inserting of the leakage preventing jig into the coupling hole, an end of the micro-needle may be sealed by disposing an end of the leakage preventing jig in the guide hole.

The providing of the micro-needle may include: providing a wire; depositing at least two metal layers on the wire; and removing the wire.

In the depositing of the at least two metal layers, nickel and gold may be sequentially deposited.

The nickel and the gold may be deposited on the wire using a sputtering method.

In the removing of the wire, the wire may be removed using an etching method.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a conceptual view illustrating a manner in which oil is injected into a spindle motor using an oil supply nozzle according to an exemplary embodiment of the present disclosure;

FIG. 2A is a perspective view of the oil supply nozzle according to an exemplary embodiment of the present disclosure;

FIG. 2B is a cross-sectional view of the oil supply nozzle according to an exemplary embodiment of the present disclosure;

FIG. 3 is a partially enlarged view of the oil supply nozzle according to an exemplary embodiment of the present disclosure;

FIG. 4A is a perspective view illustrating a form before coupling a leakage preventing jig to the oil supply nozzle according to an exemplary embodiment of the present disclosure;

FIG. 4B is a perspective view illustrating a form after coupling a leakage preventing jig to the oil supply nozzle according to an exemplary embodiment of the present disclosure; and

FIG. 5 is an enlarged cross-sectional view of portion A of FIG. 3.

### DETAILED DESCRIPTION

Exemplary embodiments of the present disclosure will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

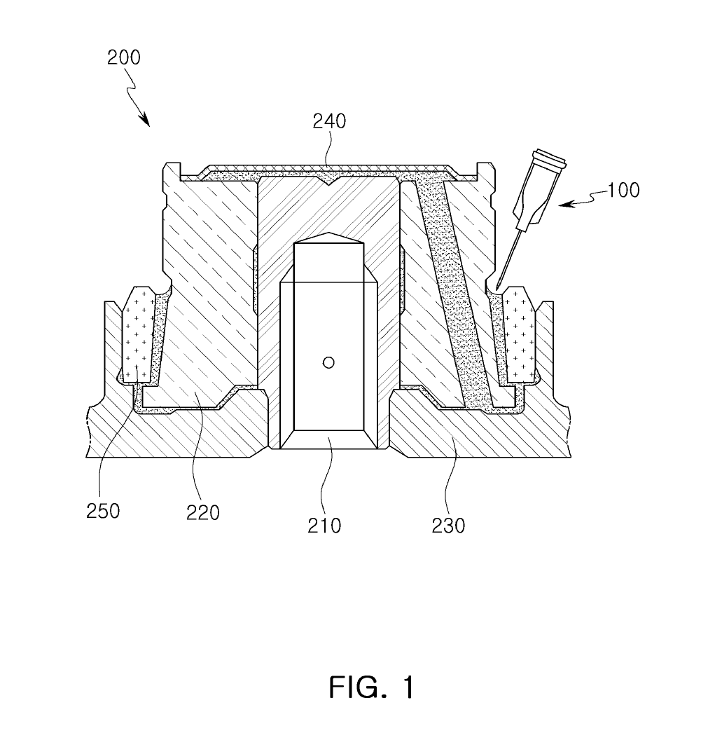

FIG. 1 is a conceptual view illustrating a manner in which oil is injected into a spindle motor using an oil supply nozzle according to an exemplary embodiment of the present disclosure.

The spindle motor of FIG. 1 may include a hydrodynamic bearing assembly 200, where the hydrodynamic bearing assembly 200 may include a shaft 210, a sleeve 220 rotatably supporting the shaft 210, a rotor 230 coupled to the shaft 210 to thereby be rotated together with the shaft 210, a cover plate 240 coupled to a lower portion of the sleeve 220, and a stopper 250 allowing oil to be sealed between the sleeve 220 and the rotor 230.

In the spindle motor of FIG. 1, the sleeve 220 and the cover plate 240 may be a fixed member, and the shaft 210, the rotor 230 and the stopper 250 may be a rotating member.

The fixed member and the rotating member have a micro-gap formed therebetween and the micro-gap has oil injected thereinto, such that the rotating member may be smoothly rotated against the fixed member by fluid pressure generated at the time of the rotation of the rotating member.

Here, the oil is injected into the gap formed between the sleeve 220 and the stopper 250 in the spindle motor. The oil may be injected into and fill the gap between the rotating member and the fixed member.

The oil may be supplied by a separate oil supply unit. As shown in FIG. 1, according to an exemplary embodiment of the present disclosure, the oil may be injected into the gap between the sleeve 220 and the stopper 250 by the oil supply nozzle 100.

In this case, the gap formed between the sleeve 220 and the stopper 250 is a gap having a micro-size and a size thereof gradually narrows according to the recent trend toward miniaturization of the spindle motor.

However, the oil supply nozzle 100 according to an exemplary embodiment of the present disclosure may allow for the injection of oil, even into a gap having a micro-size, by employing a micro-needle 110 having reduced sizes of outer and inner diameters of the needle.

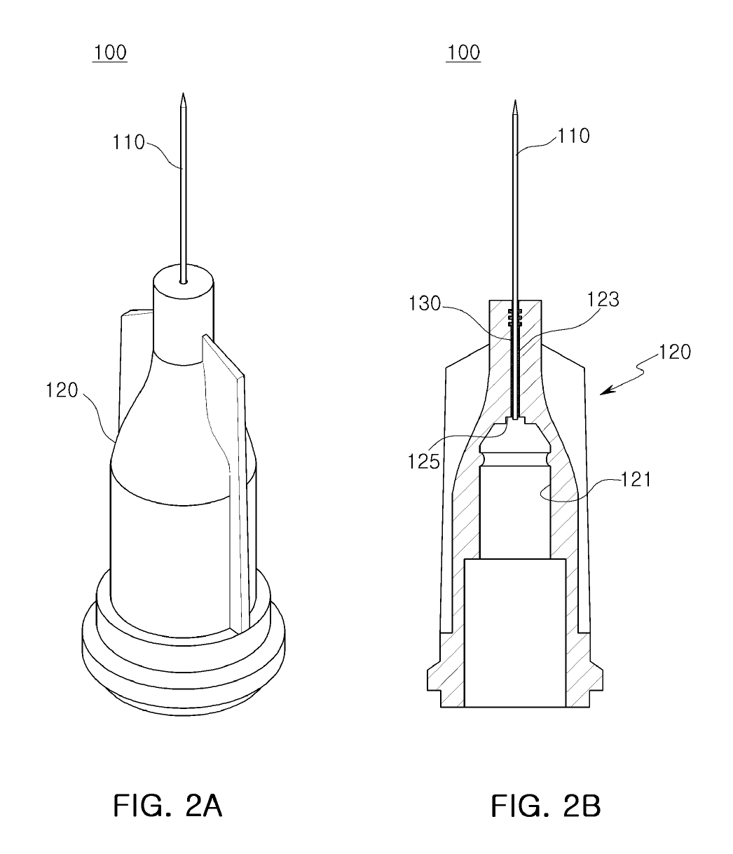

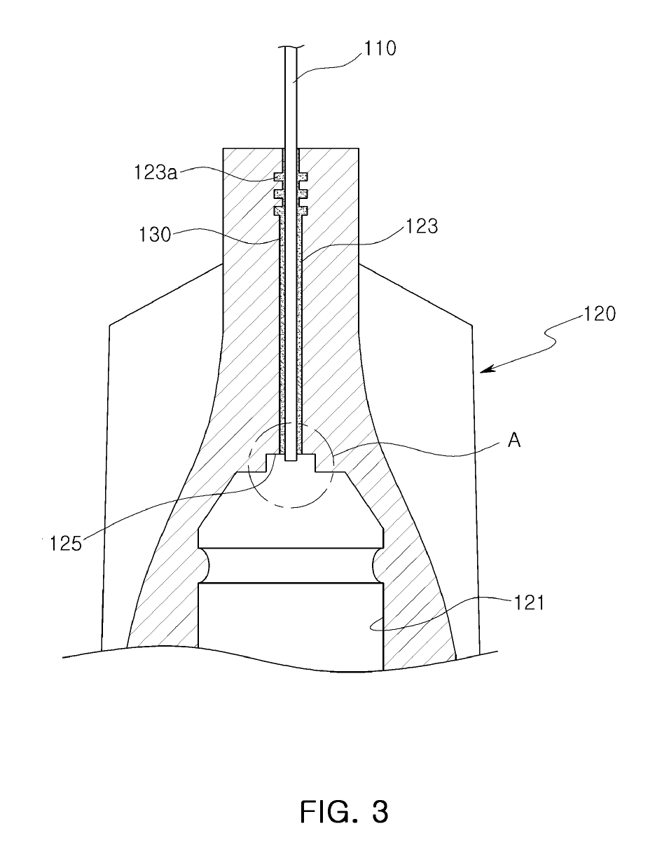

Hereinafter, the oil supply nozzle 100 according to an exemplary embodiment of the present disclosure will be described with reference to FIGS. 2A, 2B and 3.

FIG. 2A is a perspective view of the oil supply nozzle according to an exemplary embodiment of the present disclosure, FIG. 2B is a cross-sectional view of the oil supply nozzle according to an exemplary embodiment of the present disclosure, and FIG. 3 is a partially enlarged view of the oil supply nozzle according to an exemplary embodiment of the present disclosure.

Referring to FIGS. 2A, 2B and 3, the oil supply nozzle 100 according to an exemplary embodiment of the present disclosure may include a micro-needle 110 and a needle holder 120 into which the micro-needle 110 is inserted.

The micro-needle 110 may have a passage in which the oil may flow and may have a needle shape in which an inner diameter and an outer diameter have a predetermined size.

The micro-needle 110 may be inserted into and fixed to the needle holder 120 and the oil may be discharged from a tip of the micro-needle 110 exposed to the outside of the needle holder 120.

The micro-needle 110 may have the inner diameter of 150 μm to 50 μm and the outer diameter of 200 μm to 80 μm.

A manufacturing method of the micro-needle 110 capable of implementing the inner diameter and the outer diameter will be described below.

The micro-needle 110 may be inserted into and fixed to the needle holder 120 and the needle holder 120 may be inserted into a separate oil injection apparatus (not shown).

That is, the oil supplied from the oil injection apparatus (not shown) may be discharged to the tip of the micro-needle 110 via the needle holder 120 and may be finally injected into a gap between the sleeve 220 and the stopper 250.

The needle holder 120 may include a coupling hole 121 formed to allow the needle holder 120 to be inserted into the oil injection apparatus (not shown), and an insertion hole 123 connected to the coupling hole 121 and having the micro-needle 110 inserted thereinto.

In addition, a guide hole 125 may be provided at a point at which the insertion hole 123 and the coupling hole 121 are connected to each other.

Here, the guide hole 125 may be formed to have a diameter smaller than that of the coupling hole 121 and larger than that of the insertion hole 123.

The guide hole 125 may have a configuration in which an end portion of a leakage preventing jig 300 is disposed. This will be described in detail below.

The micro-needle 110 may be inserted into the insertion hole 123 so that an end thereof is disposed at the guide hole 125.

An adhesive 130 may be applied between the micro-needle 110 and an inner wall of the insertion hole 123, and the micro-needle 110 may be fixed to the needle holder 120 by the adhesive 130.

Here, in order to improve adhesion of the adhesive 130 with the insertion hole 123, the oil supply nozzle 100 according to an exemplary embodiment of the present disclosure may have at least one reservoir groove 123a formed in the inner wall of the insertion hole 123.

Therefore, the reservoir groove 123a is also filled with the adhesive 130 and a contact area is increased, such that the adhesion of the adhesive 130 with the insertion hole 123 may be improved.

In addition, even in the case that external impacts are transferred, since the adhesive 130 filled in the reservoir groove 123a may serve as a stopper, withdrawal force of the micro-needle 110 may be improved.

The inner wall of the insertion hole 123 may be formed to have a degree of surface roughness greater than that of other portions of the needle holder 120.

Since the inner wall of the insertion hole 123 is formed to have a degree of surface roughness greater than that of other portions of the needle holder 120, a contact area of the inner wall of the insertion hole 123 and the adhesive 130 may be further increased, thereby further improving the adhesion of the adhesive 130 with an inner wall of the insertion hole 123.

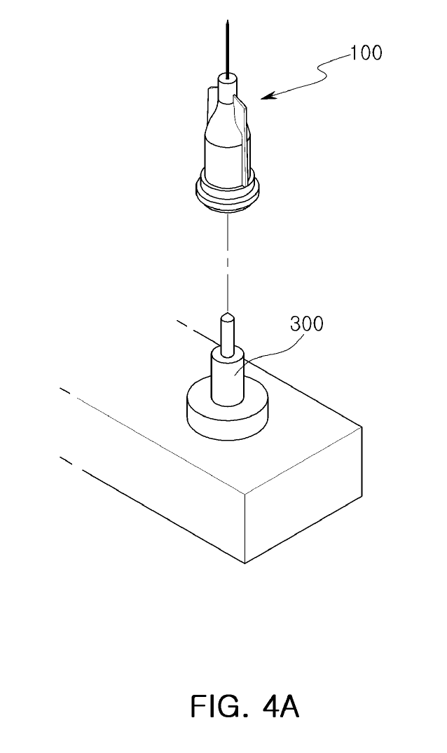

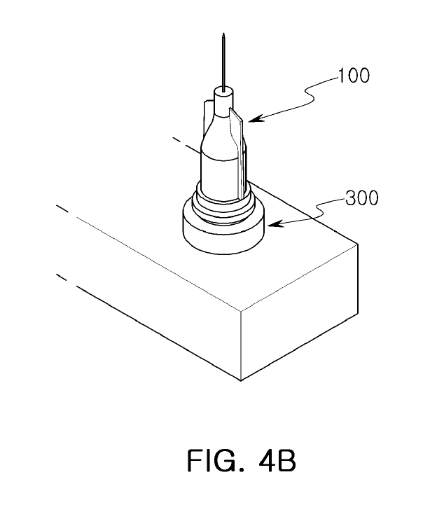

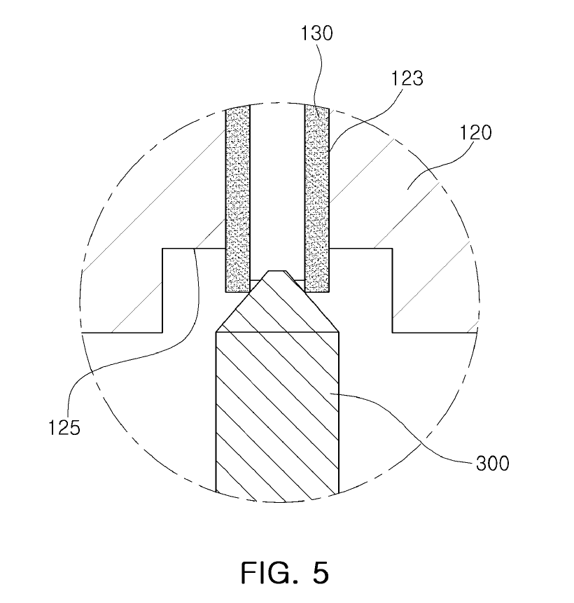

FIG. 4A is a perspective view illustrating a form before coupling a leakage preventing jig to the oil supply nozzle according to an exemplary embodiment of the present disclosure, FIG. 4B is a perspective view illustrating a form after coupling a leakage preventing jig to the oil supply nozzle according to an exemplary embodiment of the present disclosure, and FIG. 5 is an enlarged cross-sectional view of portion A of FIG. 3.

Hereinafter, a manufacturing method of the oil supply nozzle 100 according to an exemplary embodiment of the present disclosure will be described with reference to FIGS. 4A through 5.

First, a micro-needle 110 is provided.

The micro-needle 110 may be formed by depositing at least two metal layers on a wire having a predetermined diameter and then removing the wire.

Therefore, the diameter of the wire (or an inner diameter of the metal layer) may be equal to an inner diameter of the micro-needle 110 and an outer diameter of the metal layer may be equal to an outer diameter of the micro-needle 110.

Since the inner diameter and the outer diameter of the micro-needle 110 may be determined by the diameter of the wire and the outer diameter of the metal layer, the micro-needle 110 having required inner diameter and outer diameter may be manufactured by adjusting sizes of the diameter of the wire and the outer diameter of the metal layer deposited on the wire.

In detail, the at least two metal layers may be a metal layer formed of nickel and gold, and the metal layer may be formed by sequentially depositing nickel and gold on the wire.

Here, nickel and gold may be deposited on the wire using a sputtering method.

The micro-needle 110 may be manufactured by removing the wire after forming the metal layer on the wire, where the wire may be removed using an etching process.

Next, the needle holder 120 to which the micro-needle 110 is inserted and fixed is provided.

The needle holder 120 may include a coupling hole 121 into which a separate oil injection apparatus (not shown) is inserted, may include an insertion hole 123 into which the micro-needle 110 is inserted, and may include a guide hole 125 at a point at which the insertion hole 123 and the coupling hole 121 are connected to each other.

The needle holder 120 having the above-mentioned configuration may be manufactured by a plastic injection molding method.

At least one reservoir groove 123a may be formed in the inner wall of the insertion hole 123 in order to increase a contact area of an inner wall of the insertion hole 123 with an adhesive, and the inner wall of the insertion hole 123 may be formed to have a degree of surface roughness greater than that of other portions of the needle holder 120.

In addition, the guide hole 125 may be formed to have a diameter smaller than that of the coupling hole 121 and larger than that of the insertion hole 123.

Once the micro-needle 110 and the needle holder 120 are provided, the micro-needle 110 is inserted into the insertion hole 123 of the needle holder 120.

In addition, a leakage preventing jig 300 may be inserted into the coupling hole 121 of the needle holder 120.

Here, an end of the micro-needle 110 and an end of the leakage preventing jig 300 may be disposed in the guide hole 125 so that the end of the micro-needle 110 and the end of the leakage preventing jig 300 are in contact with each other.

The leakage preventing jig 300 prevents a phenomenon in which the adhesive 130 flows in the micro-needle 110 through the end of the micro-needle 110 to thereby block the micro-needle 110.

Since the end of the leakage preventing jig 300 is in contact with the end of the micro-needle 110 to thereby seal the end of the micro-needle 110, the flow of the adhesive 130 into the micro-needle 110 may be prevented.

When the end of the micro-needle 110 is sealed by the leakage preventing jig 300, the adhesive 130 is injected into a gap between the inner wall of the insertion hole 123 and the micro-needle 110, thereby fixing the micro-needle 110 to the needle holder 120.

When the fixing of the micro-needle 110 is complete, the leakage preventing jig 300 is separated and the manufacturing of the oil supply nozzle 100 according to an exemplary embodiment of the present disclosure is complete.

According to exemplary embodiment of the present disclosure, the oil may be easily injected even into the micro gap and reliability may be secured by improving the withdrawal force of the micro-needle.

As set forth above, according to exemplary embodiments of the present disclosure, the oil may be easily injected even into the micro-gap by the oil supply nozzle and the manufacturing method thereof.

In addition, reliability may be secured by improving the pulling-out force of the micro-needle.

While exemplary embodiments have been shown and described above, it will be apparent to those skilled in the art that modifications and variations could be made without departing from the spirit and scope of the present disclosure as defined by the appended claims.

What is claimed is:

1. An oil supply nozzle, comprising:
a micro-needle; and
a needle holder into which the micro-needle is inserted and fixed with an adhesive,
wherein the needle holder includes a coupling hole formed to allow the needle holder to be inserted into an oil injection apparatus, and an injection hole connected to the coupling hole and having the micro-needle inserted thereinto, and
the insertion hole and the coupling hole have a guide hole at a point of connection therebetween.

2. The oil supply nozzle of claim 1, wherein the guide hole is formed to have a diameter smaller than that of the coupling hole and larger than that of the insertion hole.

3. The oil supply nozzle of claim 1, wherein the insertion hole has at least one reservoir groove formed in an inner wall thereof in order to increase a contact area with the adhesive.

4. The oil supply nozzle of claim 1, wherein the insertion hole has an inner wall formed to have a degree of surface roughness greater than that of other portions of the needle holder.

5. A manufacturing method of an oil supply nozzle, the method comprising:
providing a micro-needle;
providing a needle holder including a coupling hole to allow for insertion into an oil injection apparatus, including an insertion hole into which the micro-needle is inserted, and including a guide hole at a point at which the insertion hole and the coupling hole are connected to each other;
inserting the micro-needle into the insertion hole;
inserting a leakage preventing jig into the coupling hole so that an end of the leakage preventing jig is disposed in the guide hole; and
injecting an adhesive into a gap between an inner wall of the insertion hole and the micro-needle.

6. The method of claim 5, further comprising forming the inner wall of the insertion hole to have a degree of surface roughness greater than that of other portions of the needle holder.

7. The method of claim 5, further comprising forming at least one reservoir groove in the inner wall of the insertion hole.

8. The method of claim 5, wherein in the inserting of the micro-needle into the insertion hole, an end of the micro-needle is disposed in the guide hole so that the end of the micro-needle is in contact with an end of the leakage preventing jig.

9. The method of claim 5, wherein in the inserting of the leakage preventing jig into the coupling hole, an end of the micro-needle is sealed by disposing an end of the leakage preventing jig in the guide hole.

10. The method of claim 5, wherein the providing of the micro-needle includes:
providing a wire;
depositing at least two metal layers on the wire; and
removing the wire.

11. The method of claim 10, wherein in the depositing of the at least two metal layers, nickel and gold are sequentially deposited.

12. The method of claim 11, wherein the nickel and the gold are deposited on the wire using a sputtering method.

13. The method of claim 10, wherein in the removing of the wire, the wire is removed using an etching method.
